(19) United States
(12) Patent Application Publication
(10) Pub. No.: US 2012/0112237 A1
(43) Pub. Date: May 10, 2012

(54) LED PACKAGE STRUCTURE

(75) Inventors: Weiwei Zheng, Guangdong (CN); Chechang Hu, Guangdong (CN)

(73) Assignee: SHENZHEN CHINA STAR OPTOELECTRONICS TECHNOLOGY CO. LTD., Guangming New District, Shenzhen (CN)

(21) Appl. No.: 12/997,915

(22) PCT Filed: Nov. 29, 2010
(86) PCT No.: PCT/CN2010/079255

§ 371 Date: Dec. 14, 2010

(30) Foreign Application Priority Data
Nov. 5, 2010 (CN) 201010536833.1

(51) Int. Cl. H01L 33/48

(52) U.S. Cl. 257/99; 257/E33.056; 257/E33.059

(57) ABSTRACT

The present invention provides an LED package structure which has a housing, a first electrode plate, a second electrode plate, a LED chip and a Zener diode. The LED chip is mounted in the recess, and a first electrode and a second electrode of the LED chip are electrically connected to the first electrode plate and the second electrode plate, respectively. The Zener diode is embedded in the housing, and a second electrode and a first electrode of the Zener diode is electrically connected to the first electrode plate and the second electrode plate, respectively. The Zener diode of the present invention is embedded in the housing, so that it can prevent from affecting the luminous flux of the LED chip.

### FIELD OF THE INVENTION

The present invention relates to a light emitting diode (LED) package structure, and more particularly to an LED package structure having a Zener diode embedded in a housing thereof.

### BACKGROUND OF THE INVENTION

A liquid crystal display (LCD) is a type of flat panel display (FPD), which shows images by the property of liquid crystal material. Comparing with other display devices, the liquid crystal display has advantages in lightweight, compactness, low driving voltage and low power consumption, and thus has already become the mainstream product in the whole consumer market. However, the liquid crystal material of the liquid crystal display cannot emit light by itself, and must depend upon an external light source. Thus, the liquid crystal display further has a backlight module to provide the needed light source.

Generally, the backlight module can be divided into two types, i.e. the side-light type backlight module and the direct-light type backlight module. Traditional backlight modules mainly use cold cathode fluorescent lamps (CCFLs), hot cathode fluorescent lamps (HCFLs) or semiconductor emitting diodes as light sources, wherein the semiconductor emitting diodes mainly use light emitting diodes (LEDs) to emit light. In comparison with the cathode fluorescent lamps, the light emitting diodes can save more electric power, have longer lifetime, and more compact volume, so that there is a trend to gradually use the light emitting diodes to replace the cathode fluorescent lamps. Thus, the light emitting diodes will be the main light sources of backlight modules in liquid crystal displays in the future.

Nowadays, an LED is generally in form of chip to be assembled to a semiconductor package, i.e. an LED package structure, which is finally connected to a fixed plate of a backlight module. Product types of the LED package structures are classified according to condition features including light colors, chip material, luminance, size and etc. A single chip generally can construct a point type light source, while a plurality of assembled chips can construct a surface type light source or a linear type light source for the purpose of signaling, indicating status, or displaying. The light emitting display is constructed by a plurality of chips suitably connected (in series or in parallel) and suitable optical structures, all of which construct light emitting sections and light emitting points of the light emitting display. Furthermore, a surface-mounting-device type LED (SMD-LED) is attached to a surface of a circuit board, so that it is suitably applied to a SMT (surface mounting technology) process for carrying out reflowing. Thus, it can efficiently solve problems of brightness, visual angle, evenness, reliability, uniformity and etc. Moreover, the SMD-LED is used with lighter material of a PCB board and a reflective layer, and omitted terminals made of carbon steel in a dip type LED, so that epoxy resin filled in a display reflective layer can be reduced, and a half of product weight of the SMD-LED can be easily removed to finally optimize the application thereof. Thus, the SMD-LED gradually replaces the terminal type LED, and can provide more flexible designs, especially occupying a market share in the LED display market and having a trend of rapidly developing.

Referring now to FIG. 1, FIG. 1 discloses a cross-sectional view of a traditional LED package structure. As shown in FIG. 1, a traditional LED package structure 90 comprises a housing 91, a first electrode plate 92, a second electrode plate 93, an LED chip 94, a Zener diode 95 and a transparent encapsulant 96. An upper surface of the housing 91 has a recess 911. A portion of the first electrode plate 92 is installed on a lower portion of the recess 911, and the other portion thereof is extended out of the housing 91 for external electrical connection. A portion of the second electrode plate 93 is installed on a lower portion of the recess 911, and the other portion thereof is extended out of the housing 91 for external electrical connection. The LED chip 94 is installed in the recess 911, and has a first electrode electrically connected to the first electrode plate 92 and a second electrode electrically connected to the second electrode plate 93 through a first wire 941. The transparent encapsulant 96 is filled in the recess 911, and encapsulates all components in the recess 911. Furthermore, light emitted by the LED chip 94 can pass through the transparent encapsulant 96 and emit upward.

However, in the traditional LED package structure 90, for preventing the LED chip 94 from being punctured by static electricity, the LED chip 94 is generally connected in parallel to one or a set of the Zener diode 95 to solve the foregoing problem. Referring to FIGS. 1 and 2, FIG. 2 is a schematic view of a circuit of the traditional LED package structure of FIG. 1. In the traditional LED package structure 90, the Zener diode 95 is installed on the housing 91, i.e. installed on the second electrode plate 93, wherein a first electrode of the Zener diode 95 is disposed a lower end thereof for being electrically connected to the second electrode plate 93, while a second electrode of the Zener diode 95 is disposed an upper end thereof for being electrically connected to the first electrode plate 92 through a second wire 951. In other words, the Zener diode 95 and the LED chip 94 are connected in parallel to each other, wherein the Zener diode 95 is reversely biased. Thus, the Zener diode 95 can protect the LED chip 94 from being punctured by static electricity. But, the Zener diode 95 is mounted on the second electrode plate 93, over the housing 91, and in the transparent encapsulant 96. However, because the appearance of the Zener diode 95 is opaque and generally dark, the Zener diode 95 has a property of blocking light and absorbing light. As a result, a portion of luminous flux of the LED chip 94 will be affected, resulting in lowering the light extraction efficiency of the LED package structure 90.

As a result, it is necessary to provide an LED package structure to solve the problems existing in the conventional technologies, as described above.

### SUMMARY OF THE INVENTION

A primary object of the present invention is to provide an LED package structure, wherein a Zener diode is embedded in a housing to prevent from affecting the luminous flux of an LED chip, so as to enhance the entire light extraction efficiency of the LED package structure.

A secondary object of the present invention is to provide an LED package structure, wherein an end of a first electrode plate or a second electrode plate is bent downward for electrically connecting to a lower end of the Zener diode embedded in the housing.

A third object of the present invention is to provide an LED package structure, wherein a portion of the first electrode plate penetrates through the housing for electrically connecting to a lower end of the Zener diode embedded in the housing.

To achieve the above object, the present invention provides an LED package structure comprising:

a housing having a recess on an upper surface thereof;

a first electrode plate, wherein a portion thereof is mounted in the recess and the other portion thereof is extended out of the housing;

a second electrode plate, wherein a portion thereof is mounted in the recess and the other portion thereof is extended out of the housing;

an LED chip mounted in the recess, wherein a first electrode of the LED chip is electrically connected to the first electrode plate, and a second electrode of the LED chip is electrically connected to the second electrode plate; and

at least one Zener diode embedded in an embedment hole of the housing, wherein a second electrode of the Zener diode is electrically connected to the first electrode plate, and a first electrode of the Zener diode is electrically connected to the second electrode plate.

In one embodiment of the present invention, the second electrode and the first electrode of the Zener diode are formed on an upper end and a lower end thereof, respectively; the first electrode plate is electrically connected to the upper end of the Zener diode, and the second electrode plate is electrically connected to the lower end of the Zener diode.

In one embodiment of the present invention, one end of the second electrode plate has a downward bent portion which is embedded in the housing and electrically connected to the lower end of the Zener diode.

In one embodiment of the present invention, the first electrode and the second electrode of the Zener diode are formed on a lower end and an upper end thereof, respectively; the second electrode plate is electrically connected to the upper end of the Zener diode, and the first electrode plate is electrically connected to the lower end of the Zener diode.

In one embodiment of the present invention, one end of the first electrode plate has a downward bent portion which is embedded in the housing and electrically connected to the lower end of the Zener diode.

In one embodiment of the present invention, the first electrode and the second electrode of the Zener diode are formed on two opposite side ends thereof, respectively; one end of the first electrode plate has a downward bent portion which is embedded in the housing and electrically connected to one of the two side ends of the Zener diode; and one end of the second electrode plate has another downward bent portion which is embedded in the housing and electrically connected to the other of the two side ends of the Zener diode.

In one embodiment of the present invention, the first electrode and the second electrode of the Zener diode are electrically connected to the corresponding second electrode plate and the corresponding first electrode plate through silver conductive adhesive, respectively; the second electrode of the LED chip is electrically connected to the second electrode plate through a wire; the LED package structure further comprises a transparent encapsulant encapsulated on the recess to cover and protect the first electrode plate, the second electrode plate and the LED chip in the recess.

To achieve the above object, the present invention further provides another LED package structure comprising:

a housing having a recess on an upper surface thereof;

a first electrode plate having an inner section, a first penetrated section, an outer section and a second penetrated section, wherein the inner section is mounted in the recess, the first penetrated section is extended outward to an outer bottom of the housing, the outer section is mounted on the outer bottom of the housing, and the second penetrated section is further extended into the housing;

a second electrode plate, wherein a portion thereof is mounted in the recess and the other portion thereof is extended out of the housing;

an LED chip mounted in the recess, wherein a first electrode of the LED chip is electrically connected to the inner section of the first electrode plate, and a second electrode of the LED chip is electrically connected to the second electrode plate; and

at least one Zener diode embedded in an embedment hole of the housing, wherein a second electrode of the Zener diode is electrically connected to the second penetrated section of the first electrode plate, and a first electrode of the Zener diode is electrically connected to the second electrode plate.

In one embodiment of the present invention, the first electrode and the second electrode of the Zener diode are formed on an upper end and a lower end thereof, respectively; the second penetrated section of the first electrode plate is electrically connected to the lower end of the Zener diode, and the second electrode plate is electrically connected to the upper end of the Zener diode.

The Zener diode of the LED package structure according to the present invention is embedded in the housing, so that it can prevent from affecting the luminous flux of the LED chip and thus enhance the entire light extraction efficiency of the LED package structure.

### DESCRIPTION OF THE DRAWINGS

FIG. 1 is a cross-sectional view of a traditional LED package structure;

FIG. 2 is a schematic view of a circuit of the traditional LED package structure of FIG. 1;

FIG. 3 is a cross-sectional view of an LED package structure according to a first embodiment of the present invention;

FIG. 4 is a partially top view of the LED package structure according to the first embodiment of the present invention;

FIG. 5 is a cross-sectional view of an LED package structure according to a second embodiment of the present invention;

FIG. 6 is a cross-sectional view of an LED package structure according to a third embodiment of the present invention; and

FIG. 7 is a cross-sectional view of an LED package structure according to a fourth embodiment of the present invention.

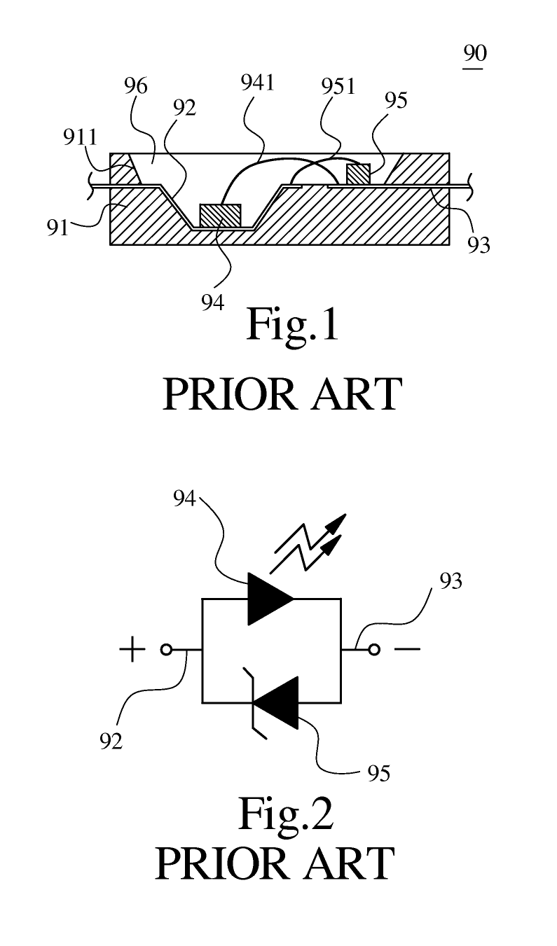

### DETAILED DESCRIPTION OF THE PREFERRED EMBODIMENTS

The structure and the technical means adopted by the present invention to achieve the above and other objects can be best understood by referring to the following detailed description of the preferred embodiments and the accompanying drawings.

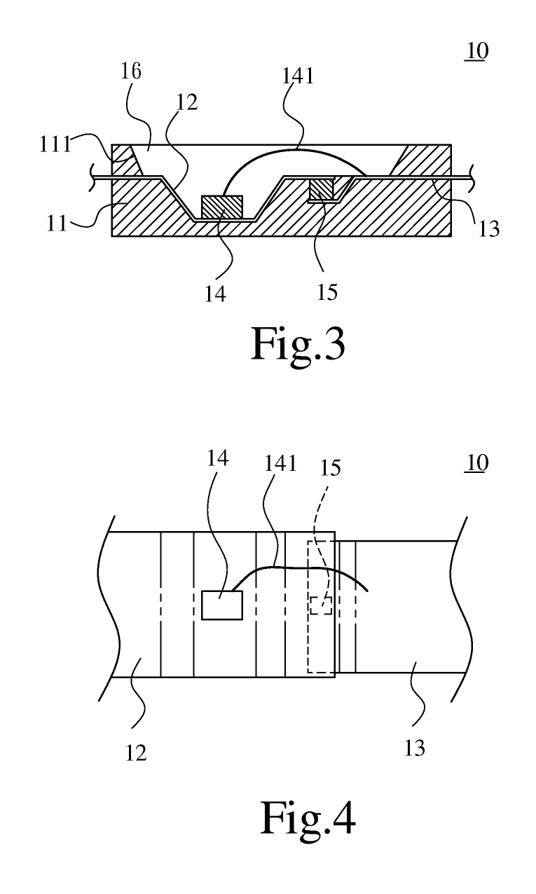

Referring now to FIGS. 3 and 4, FIG. 3 is a cross-sectional view of a light emitting diode (LED) package structure according to a first embodiment of the present invention; and FIG. 4 is a partially top view of the LED package structure according to the first embodiment of the present invention. As shown in FIGS. 3 and 4, an LED package structure 10 of the first embodiment of the present invention comprises: a housing 11, a first electrode plate 12, a second electrode plate 13, a LED chip 14 and a Zener diode 15. The housing 11 has a recess 111 on an upper surface thereof, wherein the recess 111 is a multi-stage recessed structure, and the shape thereof can be adjusted according to the desire of products. A portion of the first electrode plate 12 is mounted on a bottom of the recess 111, and the other portion thereof is extended out of the housing 11 for external electrical connection. A portion of the second electrode plate 13 is mounted on the bottom of the recess 111, and the other portion thereof is extended out of the housing 11 for external electrical connection. The LED chip 14 is mounted in the recess 111, and has a first electrode which is electrically connected to the first electrode plate 12 and a second electrode which is electrically connected to the second electrode plate 13 through a wire 141. The Zener diode 15 is mounted in the housing 11, and has a second electrode which is electrically connected to the first electrode plate 12 and a first electrode which is electrically connected to the second electrode plate 13.

The LED package structure 10 further comprises a transparent encapsulant 16 encapsulated on the recess 111 to cover and protect the first electrode plate 12, the second electrode plate 13 and the LED chip 14 in the recess 111. The material of the transparent encapsulant 16 is material which is suitably applied to encapsulation and able to be passed through by light, such as epoxy resin. The light emitted by the LED chip 14 can pass through the transparent encapsulant 16 and emit upward.

Furthermore, for preventing the LED chip 14 from being punctured by static electricity, at least one of the Zener diode 15 is provided, wherein the electrode arrangement of the Zener diode 15 is described, as follows: the second electrode is formed on an upper end thereof, and the first electrode is formed on a lower end thereof; wherein the first electrode plate 12 is electrically connected to the upper end of the Zener diode 15, and the second electrode plate 13 is electrically connected to the lower end of the Zener diode 15. The Zener diode 15 and the LED chip 14 are connected in parallel to each other, and the Zener diode 15 is reversely biased.

In the LED package structure 10 of the present invention, the Zener diode 15 is embedded in the housing 11, so that it can prevent the Zener diode 15 from affecting the luminous flux of the LED chip 14 and thus enhance the entire light extraction efficiency of the LED package structure 10.

Moreover, although the LED package structure 10 in the first embodiment of the present invention is a surface-mounting-device type LED (SMD-LED), the type of LED suitably applied to the present invention is not limited thereto. Other suitable type of LEDs, such as the thermoelectric separation type LED suitably, also can be applied to the present invention

In addition, the first electrode and the second electrode in the present invention are not limited to specific representative electrode. Generally, the first electrode may be a positive electrode, and the second electrode may be a negative electrode. However, all of electrodes may be correspondingly re-arranged according to conditions.

Besides, although the LED package structure 10 in the first embodiment of the present invention is provided with one of the Zener diode 15, the number of the Zener diode 15 in the present invention is not limited thereto. A user can embed a plurality of the Zener diode 15 according to an actual need.

Furthermore, electrode ends of each of the diode (i.e. the LED chip 14 and the Zener diode 15) can be electrically connected to the corresponding electrode plate (i.e. the first electrode plate 12 and the electrode plate 13) through silver conductive adhesive, respectively.

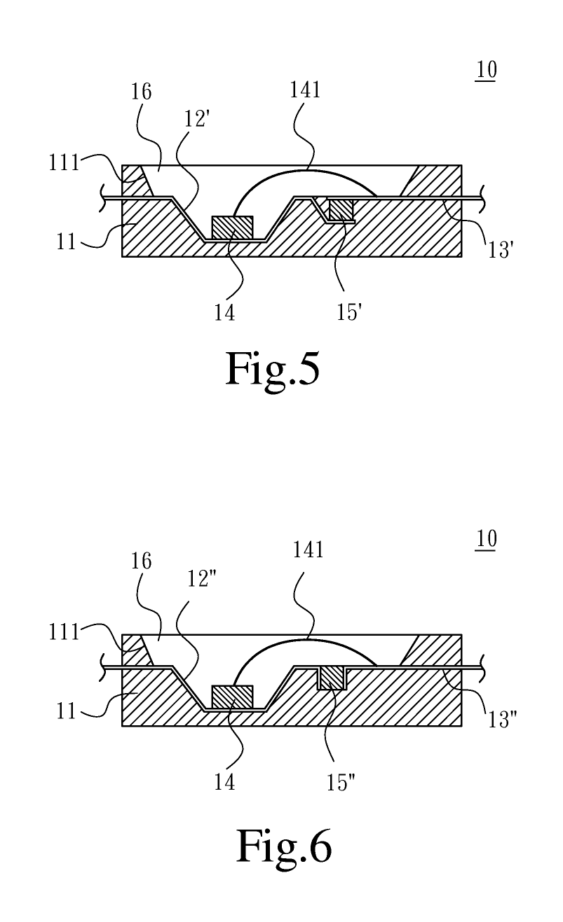

Referring now to FIG. 5, FIG. 5 is a cross-sectional view of an LED package structure according to a second embodiment of the present invention, wherein the LED package structure 10 according to the second embodiment of the present invention is similar to the LED package structure 10 according to the first embodiment of the present invention, so that the second embodiment uses similar component numerals and names of the first embodiment. However, the difference of the second embodiment is that: the electrode direction of a Zener diode 15′ according to the second embodiment of the present invention is opposite to the electrode direction of the Zener diode 15 according to the first embodiment of the present invention from top to bottom, wherein the electrode arrangement of the Zener diode 15′ is described, as follows: the first electrode is formed on an upper end thereof, and the second electrode is formed on a lower end thereof. Meanwhile, one end of a first electrode plate 12′ has a downward bent portion which is embedded under the Zener diode 15′, and the first electrode plate 12′ is electrically connected to the lower end of the Zener diode 15′. In addition, a second electrode plate 13′ is electrically connected to the upper end of the Zener diode 15′.

Referring now to FIG. 6, FIG. 6 is a cross-sectional view of an LED package structure according to a third embodiment of the present invention, wherein the LED package structure 10 according to the third embodiment of the present invention is similar to the LED package structure 10 according to the first embodiment of the present invention, so that the third embodiment uses similar component numerals and names of the first embodiment. However, the difference of the third embodiment is that: the electrode arrangement of a Zener diode 15″ according to the third embodiment of the present invention is described, as follows: the first electrode and the second electrode are formed on two opposite side ends (i.e. a left side end and a right side end) thereof, respectively; one end of a first electrode plate 12″ has a downward bent portion which is electrically connected to the second electrode on one of the two side ends (e.g. the left side end) of the Zener diode 15″; and one end of a second electrode plate 13″ has another downward bent portion which is electrically connected to the first electrode on the other of the two side ends (e.g. the right side end) of the Zener diode 15″. Thus, the Zener diode 15″ and the LED chip 14 are connected in parallel to each other, and the Zener diode 15″ is reversely biased.

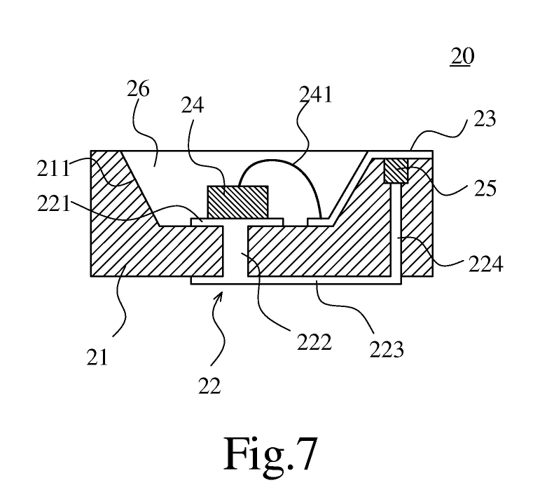

Referring now to FIG. 7, FIG. 7 is a cross-sectional view of an LED package structure according to a fourth embodiment of the present invention, wherein the LED package structure 20 according to the fourth embodiment of the present invention comprises: a housing 21, a first electrode plate 22, a second electrode plate 23, a LED chip 24 and a Zener diode 25. The housing 21 has a recess 211 on an upper surface thereof. A portion of the first electrode plate 22 is mounted on a bottom of the recess 211, and the other portion thereof is extended to an outer bottom of the housing 21 for external electrical connection. A portion of the second electrode plate 23 is mounted on the bottom of the recess 211, and the other portion thereof is extended out of the housing 21 for external electrical connection. The LED chip 24 is mounted in the recess 211. The Zener diode 25 is mounted in the housing 21. Furthermore, the LED package structure 20 further comprises a transparent encapsulant 26 encapsulated on the recess 211 to cover and protect the first electrode plate 22, the second electrode plate 23 and the LED chip 24 in the recess 211.

Moreover, a first electrode of the LED chip 24 is electrically connected to the first electrode plate 22, and a second electrode of the LED chip 24 is electrically connected to the second electrode plate 23 through a wire 241. In addition, the electrode arrangement of the Zener diode 25 is described, as follows: the first electrode is formed on an upper end thereof, and the second electrode is formed on a lower end thereof; wherein the first electrode plate 22 further comprises a portion which is electrically connected to the lower end of the Zener diode 25.

For more details, the first electrode plate 22 has an inner section 221, a first penetrated section 222, an outer section 223 and a second penetrated section 224, wherein the inner section 221 is mounted in the recess 211 and electrically connected to the first electrode of the LED chip 24, the first penetrated section 222 is connected to the outer section 223 which is mounted on the outer bottom of the housing 21, and the second penetrated section 224 is connected to the lower end of the Zener diode 25. Thus, the second electrode of the Zener diode 25 is electrically connected to the first electrode plate 22, and the first electrode of the Zener diode 25 is electrically connected to the second electrode plate 23. The Zener diode 25 and the LED chip 24 are connected in parallel to each other, and the Zener diode 25 is reversely biased.

Furthermore, referring to FIG. 7, the second penetrated section 224 can be connected to a distal end of the outer section 223, or connected to other position of the first electrode plate 22, wherein the second penetrated section 224 mainly provides the connection between the first electrode plate 22 and the second electrode of the Zener diode 25.

In the fourth embodiment of the present invention, the Zener diode 25 of the LED package structure 20 is embedded in the housing 21, so that it can prevent the Zener diode 25 from affecting the luminous flux of the LED chip 24.

As described above, in comparison with the Zener diode of the traditional LED package structure which is mounted on the housing to affect a portion of the luminous flux of the LED chip and thus lower the light extraction efficiency of the LED package structure, the LED package structure 10, 20 of the present invention is provided with a Zener diode 15, 25 which is embedded in the housing 11, 21, so that it can prevent from affecting the luminous flux of the LED chip 14,24 and thus enhance the entire light extraction efficiency of the LED package structure 10, 20.

The present invention has been described with a preferred embodiment thereof and it is understood that many changes and modifications to the described embodiment can be carried out without departing from the scope and the spirit of the invention that is intended to be limited only by the appended claims.

1. An LED package structure, characterized in that: the LED package structure comprises:
a housing having a recess on an upper surface thereof;
a first electrode plate, wherein a portion thereof is mounted in the recess and the other portion thereof is extended out of the housing;
a second electrode plate, wherein a portion thereof is mounted in the recess and the other portion thereof is extended out of the housing;
an LED chip mounted in the recess, wherein a first electrode of the LED chip is electrically connected to the first electrode plate, and a second electrode of the LED chip is electrically connected to the second electrode plate; and
at least one Zener diode embedded in an embedment hole of the housing, wherein a second electrode of the Zener diode is electrically connected to the first electrode plate, and a first electrode of the Zener diode is electrically connected to the second electrode plate.

2. The LED package structure according to claim 1, characterized in that: the second electrode and the first electrode of the Zener diode are formed on an upper end and a lower end thereof, respectively; the first electrode plate is electrically connected to the upper end of the Zener diode, and the second electrode plate is electrically connected to the lower end of the Zener diode.

3. The LED package structure according to claim 2, characterized in that: one end of the second electrode plate has a downward bent portion which is embedded in the housing and electrically connected to the lower end of the Zener diode.

4. The LED package structure according to claim 1, characterized in that: the first electrode and the second electrode of the Zener diode are formed on a lower end and an upper end thereof, respectively; the second electrode plate is electrically connected to the upper end of the Zener diode, and the first electrode plate is electrically connected to the lower end of the Zener diode.

5. The LED package structure according to claim 4, characterized in that: one end of the first electrode plate has a downward bent portion which is embedded in the housing and electrically connected to the lower end of the Zener diode.

6. The LED package structure according to claim 5, characterized in that: the LED package structure further comprises a transparent encapsulant encapsulated on the recess to cover and protect the first electrode plate, the second electrode plate and the LED chip in the recess.

7. The LED package structure according to claim 1, characterized in that: the first electrode and the second electrode of the Zener diode are formed on two opposite side ends thereof, respectively; one end of the first electrode plate has a downward bent portion which is embedded in the housing and electrically connected to one of the two side ends of the Zener diode; and one end of the second electrode plate has another downward bent portion which is embedded in the housing and electrically connected to the other of the two side ends of the Zener diode.

8. The LED package structure according to claim 1, characterized in that: the first electrode and the second electrode of the Zener diode are electrically connected to the corresponding second electrode plate and the corresponding first electrode plate through silver conductive adhesive, respectively.

9. The LED package structure according to claim 1, characterized in that: the second electrode of the LED chip is electrically connected to the second electrode plate through a wire.

10. The LED package structure according to claim 1, characterized in that: the LED package structure further comprises a transparent encapsulant encapsulated on the recess to cover and protect the first electrode plate, the second electrode plate and the LED chip in the recess.

11. An LED package structure, characterized in that: the LED package structure comprises:
a housing having a recess on an upper surface thereof;
a first electrode plate having an inner section, a first penetrated section, an outer section and a second penetrated section, wherein the inner section is mounted in the recess, the first penetrated section is extended outward to an outer bottom of the housing, the outer section is mounted on the outer bottom of the housing, and the second penetrated section is further extended into the housing;
a second electrode plate, wherein a portion thereof is mounted in the recess and the other portion thereof is extended out of the housing;
an LED chip mounted in the recess, wherein a first electrode of the LED chip is electrically connected to the inner section of the first electrode plate, and a second electrode of the LED chip is electrically connected to the second electrode plate; and
at least one Zener diode embedded in an embedment hole of the housing, wherein a second electrode of the Zener diode is electrically connected to the second penetrated section of the first electrode plate, and a first electrode of the Zener diode is electrically connected to the second electrode plate.

12. The LED package structure according to claim 11, characterized in that: the first electrode and the second electrode of the at least one Zener diode are formed on an upper end and a lower end thereof, respectively; the second penetrated section of the first electrode plate is electrically connected to the lower end of the Zener diode, and the second electrode plate is electrically connected to the upper end of the Zener diode.

13. The LED package structure according to claim 11, characterized in that: the first electrode and the second electrode of the at least one Zener diode are electrically connected to the corresponding second electrode plate and the corresponding first electrode plate through silver conductive adhesive, respectively.

14. The LED package structure according to claim 11, characterized in that: the second electrode of the LED chip is electrically connected to the second electrode plate through a wire.

15. The LED package structure according to claim 11, characterized in that: the LED package structure further comprises a transparent encapsulant encapsulated on the recess to cover and protect the first electrode plate, the second electrode plate and the LED chip in the recess.

16. An LED package structure, characterized in that: the LED package structure comprises:
a housing having a recess on an upper surface thereof;
a first electrode plate having an inner section, a first penetrated section, an outer section and a second penetrated section, wherein the inner section is mounted in the recess, the first penetrated section is extended outward to an outer bottom of the housing, the outer section is mounted on the outer bottom of the housing, and the second penetrated section is further extended into the housing;
a second electrode plate, wherein a portion thereof is mounted in the recess and the other portion thereof is extended out of the housing;
an LED chip mounted in the recess, wherein a first electrode of the LED chip is electrically connected to the inner section of the first electrode plate, and a second electrode of the LED chip is electrically connected to the second electrode plate; and
at least one Zener diode embedded in an embedment hole of the housing, wherein a second electrode of the Zener diode is electrically connected to the second penetrated section of the first electrode plate, and a first electrode of the Zener diode is electrically connected to the second electrode plate; the first electrode and the second electrode of the at least one Zener diode are formed on an upper end and a lower end thereof, respectively; the second penetrated section of the first electrode plate is electrically connected to the lower end of the Zener diode, and the second electrode plate is electrically connected to the upper end of the Zener diode.

17. The LED package structure according to claim 16, characterized in that: the first electrode and the second electrode of the at least one Zener diode are electrically connected to the corresponding second electrode plate and the corresponding first electrode plate through silver conductive adhesive, respectively.

18. The LED package structure according to claim 16, characterized in that: the second electrode of the LED chip is electrically connected to the second electrode plate through a wire.

19. The LED package structure according to claim 16, characterized in that: the LED package structure further comprises a transparent encapsulant encapsulated on the recess to cover and protect the first electrode plate, the second electrode plate and the LED chip in the recess.
